(19) United States
(12) Patent Application Publication
(10) Pub. No.: US 2026/0180505 A1
(43) Pub. Date: Jun. 25, 2026

(54) METHOD AND APPARATUS FOR MONITORING SOLAR POWER GENERATION SYSTEM

(71) Applicant: HANWHA SOLUTIONS CORPORATION, Seoul (KR)

(72) Inventors: Moon Seok CHANG, Seoul (KR); Eun Je BAEK, Seoul (KR); Young Hoon KIM, Seoul (KR)

(73) Assignee: HANWHA SOLUTIONS CORPORATION, Seoul (KR)

(21) Appl. No.: 18/848,029

(22) PCT Filed: Jul. 5, 2024
(86) PCT No.: PCT/KR2024/009608

§ 371 Date: Sep. 17, 2024

(30) Foreign Application Priority Data
Oct. 26, 2023 (KR) 10-2023-0144402

(51) Int. Cl. H02S 50/00; G01R 31/40; H02J 3/38; H02J 101/24

(52) U.S. Cl. CPC H02S 50/00; G01R 31/40; H02J 3/38; H02J 2101/25

(57) ABSTRACT

A method of monitoring a solar power generation system according to an aspect includes receiving information about a solar power generation system from an inverter, determining whether an error has occurred in the inverter or photovoltaic modules based on whether the information is received, and outputting a layout diagram of the solar power generation system based on a type of error of the photovoltaic module when an error has occurred in the photovoltaic module, and sending an alarm, wherein the determining of whether an error has occurred may include determining that an error has occurred in the inverter when the information is not received, determining whether an error has occurred in the photovoltaic module based on the information when the information is received, and determining the type of error when it is determined that an error has occurred in the photovoltaic module.

### TECHNICAL FIELD

The present disclosure relates to a method and apparatus for monitoring a solar power generation system.

### BACKGROUND ART

Recently, with the growing interest in eco-friendly energy technologies, there has been an increase in the deployment of solar power generation systems that utilize sunlight to generate energy. A solar power generation system is a system that collects solar energy through photovoltaic panels to produce electricity, and the electricity produced is supplied to the home's power grid for household use or stored in batteries for later use. Generating power with a solar power system has gained popularity in recent years because it is environmentally friendly and can save you money on your electricity bill in the long run.

Along with the development of technology for solar power generation systems, the technology for monitoring the operation or the like of the solar power generation systems and managing the solar power generation systems is recognized as an important technology. In the case of technology for managing solar power generation systems, most development focuses on methods for detecting faults in solar power generation modules and post-fault resolution methods when faults are detected.

However, conventional technology has a problem that a matching operation between unique information of each photovoltaic module and a string to which the module is connected is not performed, resulting in a failure to correspond to an actual layout in which the modules are disposed. In addition, the conventional technology has a problem in that when a photovoltaic module is replaced due to a malfunction or other reasons, it is difficult to match the monitoring information of the previous module with that of the replacement module.

Besides the errors detected by the firmware within the photovoltaic modules, no system has been developed to detect normal or abnormal power generation during the process from measuring the power generation of the solar power generation system to aggregating and transmitting information to the server, and thus, there is a need for the development of technology that detects modules in which errors have occurred and visually represents the errors on a layout diagram that corresponds to the actual layout of the modules.

### DETAILED DESCRIPTION OF INVENTION

### Technical Problem

The present disclosure is directed to providing a method and apparatus for monitoring a solar power generation system, which enables managing a layout diagram of photovoltaic modules, tracking replacement history, detecting power generation, and sending alarms for prompt error response.

The present disclosure is also directed to providing a method and apparatus for monitoring a solar power generation system, which enables easy modification of a layout diagram to correspond to an actual layout of modules, and allows real-time monitoring to check the normal operation and power generation information of the modules, thereby providing an actual position of any abnormal module.

The problems to be solved by the present disclosure are not limited to the above-mentioned problems, and other problems and advantages of the present disclosure, which are not mentioned, can be understood by the following description, and will be more clearly understood from the embodiments of the present disclosure. It will also be appreciated that the problem and advantages to be solved by the present disclosure may be implemented by the means and combinations thereof indicated in the claims.

### Technical Solution

According to an aspect of the present invention, there is provided a method of monitoring a solar power generation system including receiving information about a solar power generation system from an inverter, determining whether an error has occurred in the inverter or photovoltaic modules based on whether the information is received, and outputting a layout diagram of the solar power generation system based on a type of error of the photovoltaic module when an error has occurred in the photovoltaic module, and sending an alarm, wherein the determining of whether an error has occurred may include determining that an error has occurred in the inverter when the information is not received, determining whether an error has occurred in the photovoltaic module based on the information when the information is received, and determining the type of error when it is determined that an error has occurred in the photovoltaic module.

In the present disclosure, the determining of whether an error has occurred may include determining the type of error by obtaining a unique identifier of the photovoltaic module, in which an error has occurred, when the information is received and it is determined that an error has occurred in the photovoltaic module based on the information.

In the present disclosure, the determining of whether an error has occurred may include determining the type of error based on the number of photovoltaic modules with a maximum power generation of zero and a duration of the maximum power generation of zero in the received information.

In the present disclosure, the determining of whether an error has occurred may include determining that the error is a first type of error when there is one photovoltaic module with the maximum power generation of zero and the duration of the maximum power generation of zero is greater than or equal to a predetermined period of time, determining that the error is a second type of error when there are two or more photovoltaic modules with the maximum power generation of zero and the duration of the maximum power generation of zero is greater than or equal to a predetermined period of time, and determining that the error is a third type of error when the number of photovoltaic modules with the maximum power generation of zero is half or more of the total number of a plurality of photovoltaic modules and the duration of the maximum power generation of zero is greater than or equal to a predetermined period of time.

In the present disclosure, the outputting of the layout diagram may include outputting the layout diagram that corresponds to an actual arrangement of the photovoltaic modules, with different colors mapped for each type of error.

In the present disclosure, the sending of the alarm may include sending the alarm corresponding to the type of error for the solar power generation system to which the unique identifier is assigned.

According to another aspect of the present invention, there is provided an apparatus for monitoring a solar power generation system including at least one memory, and at least one processor, wherein the at least one processor may be configured to receive information about a solar power generation system from an inverter, determine whether an error has occurred in the inverter or photovoltaic modules based on whether the information is received, and output a layout diagram of the solar power generation system based on a type of error of the photovoltaic module when an error has occurred in the photovoltaic module, and send an alarm, and the at least one processor may be further configured to determine that an error has occurred in the inverter when the information is not received, determine whether an error has occurred in the photovoltaic module based on the information when the information is received, and determine the type of error when it is determined that an error has occurred in the photovoltaic module.

In addition, another method for implementing the present disclosure, another system, and a computer-readable recording medium storing a computer program for executing the method may be further provided.

Other aspects, features, and advantages other than those described above will become apparent from the following drawings, claims, and detailed description of the disclosure.

### Effects of Invention

According to an embodiment of the present disclosure, it is possible to check in real-time the power generation of each photovoltaic module on a layout diagram that corresponds to the actual arrangement of the modules, and to graphically confirm power generation data by matching monitoring information of the previous module with that of the replacement module, regardless of a replacement history of the modules.

In addition, there is an effect of detecting abnormalities in power generation and providing information to a user, enabling the user to take action on errors occurring in each module quickly.

Effects of the present disclosure are not limited to those mentioned above, and other effects that are not mentioned will be clearly understood by those skilled in the art from the description below.

### BRIEF DESCRIPTION OF THE DRAWINGS

FIG. 1 is an exemplary diagram for describing an example of an apparatus for monitoring a solar power generation system.

FIG. 2 is an exemplary diagram for describing a method of monitoring a solar power generation system.

FIG. 3 is an exemplary diagram for describing a configuration of a solar power generation system according to an embodiment.

FIG. 4 is an exemplary diagram for describing a method of determining the type of error that occurs in a photovoltaic module according to an embodiment.

FIG. 5 is an exemplary diagram for describing a method of outputting a layout diagram of the solar power generation system according to an embodiment.

FIG. 6 is an exemplary diagram for describing a first type of error that occurs in the photovoltaic module according to an embodiment.

FIG. 7 is an exemplary diagram for describing a second type of error that occurs in the photovoltaic module according to an embodiment.

FIG. 8 is an exemplary diagram for describing a third type of error that occurs in the photovoltaic module according to an embodiment.

### BEST MODE

A method of monitoring a solar power generation system according to an aspect includes receiving information about a solar power generation system from an inverter, determining whether an error has occurred in the inverter or photovoltaic modules based on whether the information is received, and outputting a layout diagram of the solar power generation system based on a type of error of the photovoltaic module when an error has occurred in the photovoltaic module, and sending an alarm, wherein the determining of whether an error has occurred may include determining that an error has occurred in the inverter when the information is not received, determining whether an error has occurred in the photovoltaic module based on the information when the information is received, and determining the type of error when it is determined that an error has occurred in the photovoltaic module.

### Embodiments of Invention

The advantages and features of the present disclosure and methods of achieving them will be apparent from the embodiments that will be described in detail with reference to the accompanying drawings. However, the present disclosure is not limited to the following embodiments, but may be implemented in various forms different from each other, and is to be understood to include all modifications, equivalents, or substitutions that may be implemented in a variety of different forms and that are within the scope of the ideas and techniques of the present disclosure. The embodiments presented below are only provided to make the disclosure of the present disclosure complete and fully inform those skilled in the technical field to which the present disclosure pertains of the scope of the present disclosure. In describing the present disclosure, a detailed description of known related arts will be omitted when it is determined that the gist of the present disclosure may be unnecessarily obscured.

The terms used herein are for the purpose of describing particular embodiments only and are not intended to be limiting to the present disclosure. The phrases “in some embodiments” or “in an embodiment” that appear in various places in this specification do not necessarily all refer to the same embodiment. Singular forms are intended to include plural forms as well, unless the context clearly indicates otherwise. In the present application, it will be further understood that the terms “comprise,” “comprising,” “include,” and/or “including,” when used in this specification, specify the presence of stated features, integers, steps, operations, constituent elements, components and/or groups thereof but do not preclude the presence or addition of one or more other features, integers, steps, operations, constituent elements, components and/or groups thereof.

In addition, a connection line or a connection member between components shown in the drawings is merely a functional connection and/or a physical or circuit connection. In an actual apparatus, connections between components may be represented by various functional connections, physical connections, or circuit connections that are replaceable or added.

The present embodiments may be susceptible to various modifications and include various forms, and some embodiments will be illustrated in the drawings and described in detail. However, it should be understood that there is no intent to limit the present embodiments to the particular forms disclosed, but on the contrary, the present embodiments are to cover particular modifications, equivalents, and alternatives falling within the spirit and scope of the present embodiments. The terms used in the present specification are only used to describe the embodiments and are not intended to limit the present embodiments.

Unless otherwise defined, the terms used herein have the same meaning as commonly understood by those skilled in the art to which present embodiments belong. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Detailed descriptions of the present disclosure will be made below with reference to the accompanying drawings illustrating specific embodiments in which the present disclosure may be implemented by way of example. These embodiments are described in sufficient detail to enable those skilled in the art to practice the present disclosure. It is to be understood that various embodiments of the present disclosure are different from each other, but need not be mutually exclusive. For example, specific shapes, structures, and characteristics described herein may be changed from one embodiment to another embodiment and implemented without departing from the spirit and scope of the present disclosure. In addition, it should be understood that positions or arrangements of individual components in each embodiment may be changed without departing from the spirit and scope of the present disclosure. Accordingly, the detailed description described below is not implemented in a limiting sense, and the scope of the present disclosure may encompass the scope claimed by claims and all scopes equivalent thereto. In drawings, the like reference numerals denote the same or similar components over various aspects.

Hereinafter, various embodiments of the present disclosure will be described in detail with reference to the accompanying drawings in order to enable those of ordinary skill in the art to easily practice the present disclosure.

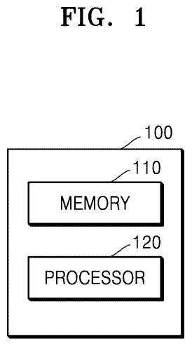

FIG. 1 is an exemplary diagram for describing an example of an apparatus for monitoring a solar power generation system.

Referring to FIG. 1, an apparatus 100 for monitoring a solar power generation system (hereinafter referred to as an “apparatus”) may include a memory 110 and a processor 120.

The apparatus 100 shown in FIG. 1 illustrates only constituent elements related to the present embodiments, and it will be apparent to those skilled in the art that other general-purpose elements may be included in addition to the constituent elements illustrated in FIG. 1.

For example, the apparatus 100 may be implemented as various types of devices, including a notebook personal computer (PC), a desktop PC, a laptop, a tablet computer, a mobile device including a smartphone, a server device, an embedded device, and the like. As a specific example, the apparatus 100 may correspond to a smartphone, a tablet device, an augmented reality (AR) device, an Internet-of-Things (IoT) device, an autonomous vehicle, or the like capable of performing voice recognition, image recognition, image classification, and the like using artificial intelligence, but the present disclosure is not limited thereto. Furthermore, the apparatus 100 may include a dedicated hardware accelerator (HW accelerator) installed in the above-described device, or may include a hardware accelerator such as a neural processing unit (NPU), a tensor processing unit (TPU), or a neural engine that is a dedicated module for driving artificial intelligence.

The memory 110 is hardware that stores various pieces of data processed in the apparatus 100, and may include a computer-readable recording medium. For example, the memory 110 may store pieces of data processed and to be processed in the apparatus 100. In addition, the memory 110 may store applications, drivers, and the like to be driven by the apparatus 100. The memory 110 may include at least one of a volatile memory or a nonvolatile memory. The volatile memory may include a dynamic random access memory (DRAM), a static random access memory (SRAM), a synchronous dynamic random access memory (SDRAM), a phase-change random access memory (PRAM), a magnetic random access memory (MRAM), resistive random access memory (RRAM), a ferroelectric random access memory (FeRAM), and the like. The non-volatile memory may include a read-only memory (ROM), a programmable read-only memory (PROM), an electrically programmable read-only memory (EPROM), an electrically erasable programmable read-only memory (EEPROM), and the like.

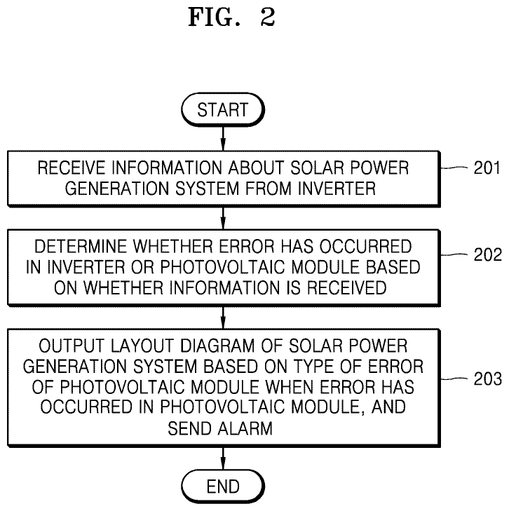

In the embodiment, the memory 110 may include magnetic memory, a CD-ROM, a Blu-ray or other optical disk storage, a hard disk drive (HDD), a solid state drive (SSD), a compact flash (CF), a secure digital (SD), a micro secure digital (Micro-SD), a mini secure digital (Mini-SD), an extreme digital (xD), or a memory stick, but the present disclosure is not limited thereto. In addition, the memory 110 may store an operating system and at least one program code (the code to be executed by the processor 120 for operations to be illustrated with reference to FIGS. 2 to 8).

The processor 120 may serve to control overall functions necessary for operating the apparatus 100, as will be described with reference to FIGS. 2 to 8. For example, by executing software (e.g., a program) stored in the memory 110 within the apparatus 100, the processor 110 may control at least one or more other constituent elements (e.g., hardware or software constituent elements) of an electronic device connected to the processor 120 and control the overall operation of the apparatus 100 through various data processing and computational tasks.

For example, the processor 120 may receive information about a solar power generation system from an inverter. In addition, the processor 120 may determine whether an error has occurred in the inverter or photovoltaic module based on whether the information is received. Specifically, it is determined that an error has occurred in the inverter when the information is not received, whether an error has occurred in the photovoltaic module is determined based on the information when the information is received, and the type of error may be determined when it is determined that an error has occurred in the photovoltaic module. In this case, the processor 120 may determine the type of error based on the number of photovoltaic modules with the maximum power generation of zero and a duration of the maximum power generation of zero in the received information. More specifically, the processor 120 may determine that the error is a first type of error when there is one photovoltaic module with the maximum power generation of zero and the duration of the maximum power generation of zero is greater than or equal to a predetermined period of time, may determine that the error is a second type of error when there are two or more photovoltaic modules with the maximum power generation of zero and the duration of the maximum power generation of zero is greater than or equal to the predetermined period of time, and may determine that the error is a third type of error when the number of the photovoltaic modules with the maximum power generation of zero is half or more of the total number of a plurality of photovoltaic modules and the duration of the maximum power generation of zero is greater than or equal to a predetermined period of time.

In addition, when an error occurs in the photovoltaic module, the processor 120 may output a layout diagram of the solar power generation system based on the type of error that occurred in the photovoltaic module, and may send an alarm. Specifically, the processor 120 may output a layout diagram that corresponds to the actual arrangement of the photovoltaic modules, with different colors mapped for each type of error. Further, the processor 120 may send an alarm corresponding to the type of error for a solar power generation system for which a unique identifier has been obtained.

According to an embodiment, the processor 120 may be implemented as a central processing unit (CPU), a graphics processing unit (GPU), an application processor (AP), a neural processing unit (NPU), an image signal processor (ISP), a sensor hub processor, a communication processor (CP), or the like provided in the apparatus 100, but the present disclosure is not limited thereto.

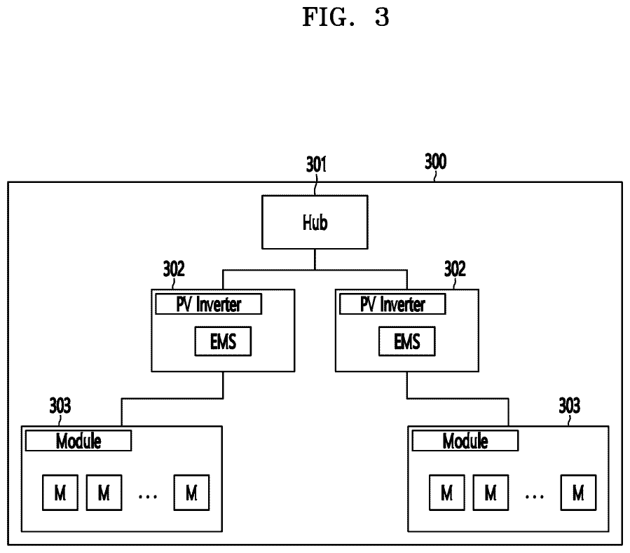

FIG. 2 is an exemplary diagram for describing a method of monitoring a solar power generation system, and FIG. 3 is an exemplary diagram for describing a configuration of a solar power generation system according to an embodiment.

Referring to FIGS. 2 and 3 together, in operation 201, the processor 120 may receive information about the solar power generation system from an inverter 302.

The solar power generation system may include a plurality of photovoltaic modules 303, a plurality of inverters 302, and a hub server 301. The plurality of photovoltaic modules 303 may be connected to a string to form a photovoltaic panel, and a module-level power electronics (MLPE) attached to the photovoltaic panel may transmit monitoring information, including information about power generation, temperature, fault information, or the like of each of the photovoltaic modules 303, and unique information of the MLPE to the inverter 302. At this time, the unique information of the MLPE sent to the inverter 302 may include a serial number.

The inverter 302 may aggregate and send the monitoring information and the unique information received from the MLPE to the hub server 301, and the hub server 301, which is the apparatus 100 for monitoring the solar power generation system of FIG. 1, may include the memory 110 and the processor 120. Accordingly, the processor 120 may receive the monitoring information and unique information of the MLPE, which are information for the solar power generation system, from the inverter 302.

In operation 202, the processor 120 may determine whether an error has occurred in the inverter 302 or the photovoltaic module 303 based on whether the information is received.

That is, the processor 120 may determine that an error has occurred in the inverter 320 when the information is not received, may determine whether an error has occurred in the photovoltaic module 303 based on the information when the information is received, and may determine the type of error when it is determined that an error has occurred in the photovoltaic module 303.

Specifically, the processor 120 may determine that an error has occurred in the photovoltaic module 303 when receiving information from the inverter 302 indicating that the maximum power generation is zero (0), and may also determine that an error has occurred in the inverter 302 when requesting the inverter 302 to send information but not receiving any information within a predetermined period of time.

In addition, when the processor 120 receives unique information of the MLPE from the inverter 302 and determines that an error has occurred in the photovoltaic module 303 based on the unique information, the processor 120 may obtain a unique identifier (UID) of the photovoltaic module 303 in which the error occurred. The unique identifier may refer to a unique slot number of the photovoltaic module 303, and while the serial number of the photovoltaic module 303 may change when the photovoltaic module 303 is replaced, the unique identifier obtained by the processor 120 may remain unchanged. Using this, the processor 120 can track a change history of the photovoltaic modules 303 in the slot.

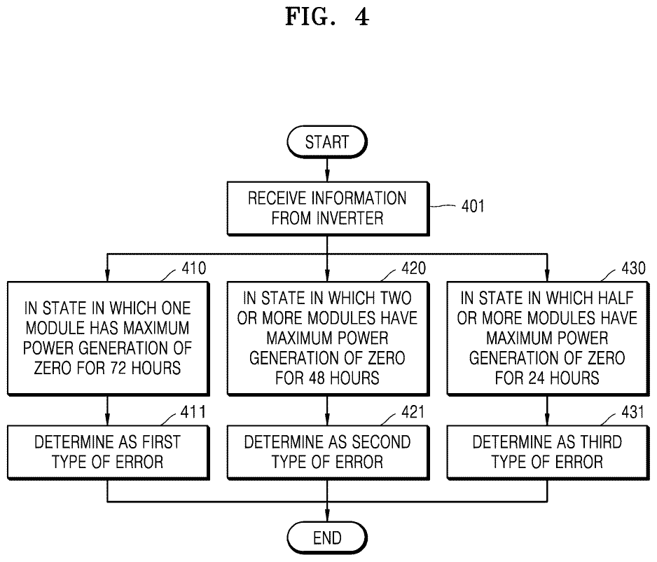

The processor 120 may determine the type of error based on the number of photovoltaic modules 303 with the maximum power generation of zero and a duration of the maximum power generation of zero in the information received from the inverter 302, and detailed descriptions thereof will be provided later with reference to FIG. 4.

In operation 203, the processor 120 may output a layout diagram of the solar power system and send an alarm based on the type of error.

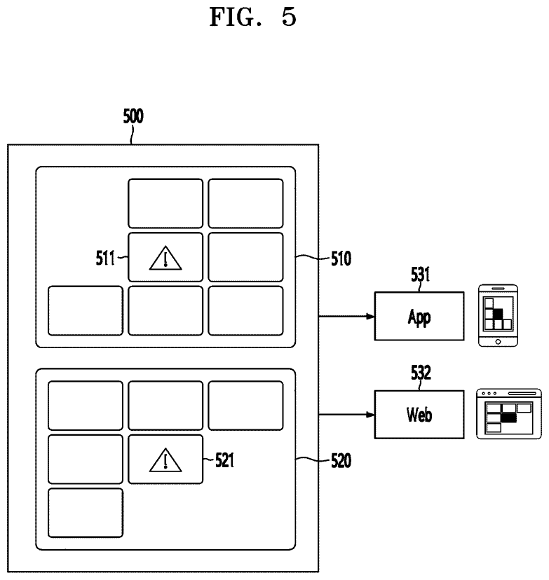

The layout diagram of the solar power system is a virtual layout diagram that corresponds to a layout in which the photovoltaic modules 303 are actually disposed, allowing the user to monitor the information of the photovoltaic modules 303 in real-time using the layout diagram. The processor 120 can visually indicate the photovoltaic module 303 in which an error has occurred on the layout diagram based on the type of error that occurred, and detailed descriptions thereof will be provided later with reference to FIG. 5.

In addition, the processor 120 may send an alarm to the user including information about the error. Specifically, the processor 120 may extract information about the error occurring in the photovoltaic module 303 or the inverter 302 and may send an alarm to the user when alarm-sending conditions are met. The alarm-sending conditions may include whether to send an alarm for each error, an alarm sending cycle, a user's consent to receive an alarm, an alarm receiving cycle, an alarm receiving account, alarm receiving equipment, and the like, but the present disclosure is not limited thereto. In addition, the processor 120 may send an alarm only for an error occurring in the photovoltaic module 303 for which a unique identifier has been obtained.

The user may modify the information about the consent to receive an alarm, the alarm receiving cycle, the alarm receiving account, the alarm receiving equipment, and the like, and may modify the alarm-sending conditions either entirely or partially.

When the alarm-sending conditions are modified, the processor 120 may send an alarm based on the updated alarm-sending conditions.

Further, once the error has been resolved or fixed, the processor 120 may send an alarm including information about the resolution or fixing of the error.

Thus, when an error occurs, is detected, is resolved, or is fixed, the processor 120 may send an alarm including information about the occurrence, detection, resolution, or fixing of the error to users, including power generation operators and power plant installers, and the types of alarms may include messages, emails, app push notifications, and the like, but the present disclosure is not limited thereto.

In addition, when there is the photovoltaic module 303 that is not connected to the string, the processor 120 may continuously send an alarm regarding the corresponding photovoltaic module 303, and the processor 120 may send an alarm at a predetermined time period aggregating errors that have occurred in the solar power generation system.

FIG. 4 is an exemplary diagram for describing a method of determining the type of error that occurs in the photovoltaic module according to an embodiment.

Referring to FIG. 4, the processor 120 may receive (401) information about the solar power generation system from the inverter 302 and determine whether an error has occurred in the inverter 302 or the photovoltaic module 303 based on the received information. Specifically, the processor 102 may determine that an error has occurred in the inverter 302 when not receiving the information from the inverter 302, the processor 120 may aggregate the received information from the inverter 302 for a predetermined period of time to determine whether an error has occurred in the photovoltaic module 303 when receiving (401) the information from the inverter 302, and the processor 120 may determine the type of error when it is determined that an error has occurred in the photovoltaic module 303.

Further, the processor 120 may perform any one of inserting, modifying, or deleting the received information in a database (DB), and may determine whether an error has occurred and the type of error by extracting information about a previously occurred error or the photovoltaic module 303, in which the error occurred, from the database and comparing the extracted information with the information received from the inverter 302. For example, the third type of error may be a higher-level error than the second and first types of errors, and the second type of error may be a higher-level error than the first type of error, but the present disclosure is not limited thereto.

The processor 120 may determine that the first type of error has occurred in the solar power generation system when there is one module with the maximum power generation of zero for a predetermined period of time, and according to an embodiment, the predetermined period of time may be 72 hours, but the present disclosure is not limited thereto.

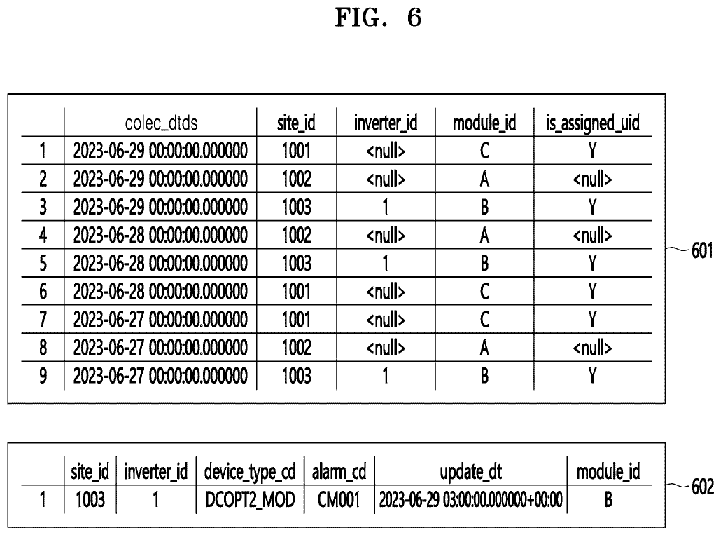

For example, the processor 120 may receive information from the inverter 302 about a first photovoltaic module with the maximum power generation of zero for 24 hours, and then aggregate this information with information in the database showing that the first photovoltaic module had the maximum power generation of zero for the previous 48 hours, and based on a state (410) of having the maximum power generation of zero for 72 hours, the processor 120 may determine (411) that the first type of error has occurred in the solar power generation system. Detailed descriptions thereof will be provided later with reference to FIG. 6.

The processor 120 may determine that the second type of error has occurred in the solar power generation system when there are two or more modules with the maximum power generation of zero for a predetermined period of time, and according to an embodiment, the predetermined period of time may be 48 hours, but the present disclosure is not limited thereto.

For example, the processor 120 may receive information from the inverter 302 about first and second photovoltaic modules with the maximum power generation of zero for 24 hours, and then aggregate this information with information in the database showing that the first and second photovoltaic modules had the maximum power generation of zero for the previous 24 hours, and based on a state (420) of having the maximum power generation of zero for 48 hours, the processor 120 may determine (421) that the second type of error has occurred in the solar power generation system.

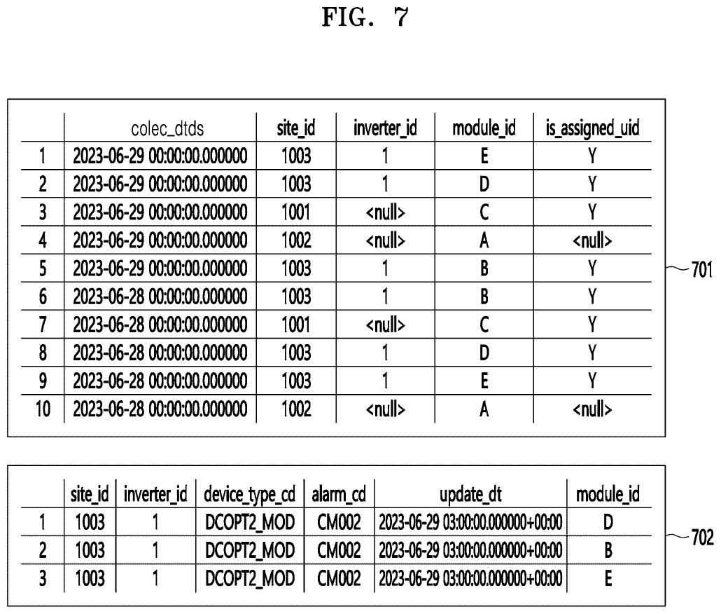

Detailed descriptions thereof will be provided later with reference to FIG. 7.

The processor 120 may determine that the third type of error has occurred in the solar power generation system when there are half or more of the total number of modules with the maximum power generation of zero for a predetermined period of time, and according to an embodiment, the predetermined period of time may be 24 hours, but the present disclosure is not limited thereto.

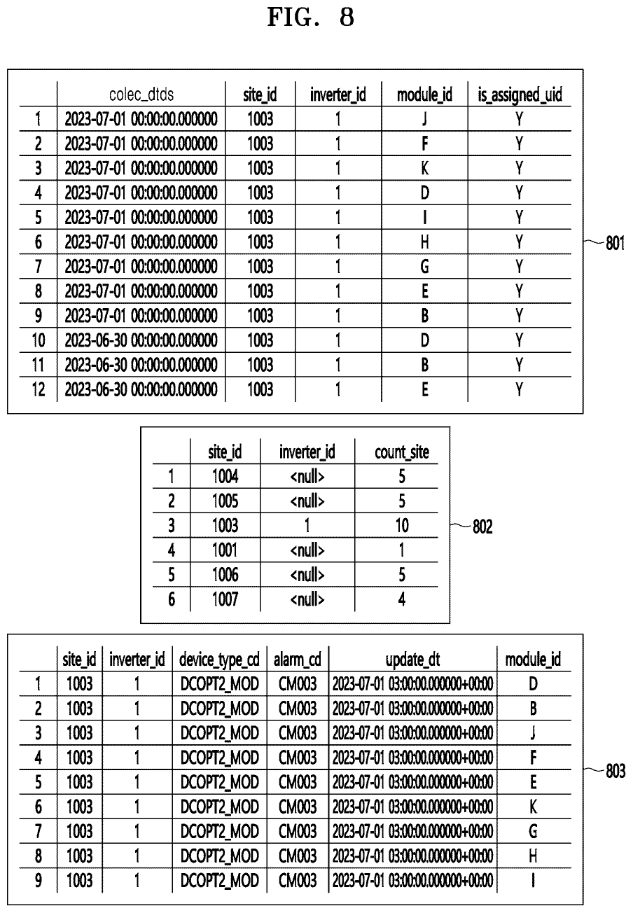

For example, the processor 120 may receive information from the inverter 302 about first to sixth photovoltaic module with the maximum power generation of zero for 24 hours, and when the number of photovoltaic modules 303 forming the solar power generation system is 10, and based on a state (430) that the first to sixth photovoltaic modules have the maximum power generation of zero for 24 hours, the processor 120 may determine (431) that the third type of error has occurred in the solar power generation system. Detailed descriptions thereof will be provided later with reference to FIG. 8.

FIG. 5 is an exemplary diagram for describing a method of outputting the layout diagram of the solar power generation system according to an embodiment.

Referring to FIG. 5, the processor 120 may output a layout diagram 500 of the solar power generation system, and a user may check the layout diagram 500 using an application 531 or a web 532. In this case, the layout diagram 500 may refer to a visualization of photovoltaic panels 510 and 520 based on a layout in which the photovoltaic modules 303 are actually disposed. In addition, the user may move the position of the photovoltaic module 303 on the layout diagram 500 using methods such as drag and drop.

The user may monitor the photovoltaic panels 510 and 520 or the photovoltaic modules 303 using the layout diagram 500. Specifically, the processor 120 may map information such as real-time power generation, accumulated power generation, temperature, and the like of the photovoltaic module 303 received from the inverter 302 to the corresponding photovoltaic module in the layout diagram 500. Thus, the user can monitor the arrangement, status, normal power generation, and information transmission status of each photovoltaic module through the layout diagram 500, and check the power generation, replacement history, and the like for each slot.

The processor 120 can visualize and represent photovoltaic modules 511 and 521 in which errors and abnormalities occur. Specifically, the processor 120 may map icons corresponding to the type of error to the photovoltaic modules 511 and 521 in which abnormalities have occurred, and may map the icons by reflecting color codes for each type of error. For example, when the first type of error occurs, the processor 120 may output the layout diagram 500 that maps the photovoltaic modules 511 and 521 or the photovoltaic panels 510 and 520 in which abnormalities have occurred in yellow. In addition, when the second type of error occurs, the processor 120 may output the layout diagram that maps the plurality of photovoltaic modules or photovoltaic panels in which abnormalities have occurred in orange. In addition, when the third type of error occurs, the processor 120 may output the layout diagram that maps the plurality of photovoltaic modules or photovoltaic panels in which abnormalities have occurred in red.

In addition, when a plurality of types of errors occur, the processor 120 may output a layout reflecting only the icon or color code corresponding to the highest-level error, and when the highest-level error is resolved, the processor 120 may output a layout reflecting the icon or color code corresponding to a next lower-level error.

FIG. 6 is an exemplary diagram for describing the first type of error that occurs in the photovoltaic module according to an embodiment.

Referring to FIG. 6, the processor 120 may determine that the first type of error has occurred in the solar power generation system when there is one photovoltaic module 303 with the maximum power generation of zero for a first period of time for the same inverter 302. Hereinafter, for convenience of description, the first period of time is described as being 72 hours, but the present disclosure is not limited thereto.

For example, the processor 120 may receive information about photovoltaic modules A, B, and C with the maximum power generation of zero from the inverter 302 and update a database (601). That is, the processor 120 may receive and reflect in the database 601 the information received from the inverter 302 about a time (colec_dtds) of receiving the information that the maximum power generation of the photovoltaic module is zero, a position (site_id) of the photovoltaic panel including the photovoltaic module, an inverter number (inverter id), a name (module_id) of the photovoltaic module, and whether (is_assigned_uid) a unique identifier is assigned to the photovoltaic module. In this case, when a number is not assigned to the inverter, “<null>” may be reflected by the processor 120, and “Y” may be reflected when a unique identifier is assigned to the photovoltaic module, and “<null>” may be reflected when a unique identifier is not assigned, but the present disclosure is not limited thereto.

The processor 120 may extract information (602) about the photovoltaic module, which is connected to the inverter to which an identifier is assigned and has a unique identifier assigned thereto, and send an alarm including this information to the user when the alarm-sending conditions are met. In this case, the information included in the alarm sent to the user may include the position (site_id) of the photovoltaic panel, the inverter number (inverter id), a type (device type_cd) of the photovoltaic module, a type of error (alarm cd), a time (update dt) the database was updated when the error was determined to have occurred, and the name (module_id) of the photovoltaic module, but the present disclosure is not limited thereto.

For example, the processor 120 may receive information about the photovoltaic modules having the maximum power generation of zero for a period from 00:00:00 to 23:59:59 on 2023 Jun. 26 at 00:00:00 on 2023 Jun. 27 and reflect this information in the database 601. In this case, module A may refer to a photovoltaic module in which an identifier is not assigned to the inverter and which does not have a unique identifier assigned. Accordingly, although the processor 120 may have received information Indicating that module A has the maximum power generation of zero on Jun. 27, 28, and 29, 2023, since module A is a photovoltaic module in which a number is not assigned to the inverter and which does not have a unique identifier assigned, module A does not satisfy the alarm-sending conditions, and thus, the processor 120 may not send an alarm including information about module A to the user.

Module B may refer to a photovoltaic module that is connected to inverter number 1 and has a unique identifier assigned thereto. Accordingly, based on the information received on Jun. 27, 28, and 29, 2023 indicating that module B has the maximum power generation of zero, the processor 120 may send an alarm to the user including information about module B.

Module C may refer to a photovoltaic module in which a number is not assigned to the inverter and which has a unique identifier assigned thereto. Accordingly, although the processor 120 may have received information indicating that module C has the maximum power generation of zero on Jun. 27, 28, and 29, 2023, since module C is a photovoltaic module in which a number is not assigned to the inverter, module C does not satisfy the alarm-sending conditions, and thus, the processor 120 may not send an alarm including information about module C to the user.

Accordingly, based on the fact that only one module, module B, satisfies the alarm-sending conditions according to the information about modules A, B, and C received on Jun. 27, 28, and 29, 2023, the processor 120 may determine that the error occurring in the solar power generation system is the first type of error (CM001), and then send an alarm to the user including this information.

FIG. 7 is an exemplary diagram for describing the second type of error that occurs in the photovoltaic module according to an embodiment.

Referring to FIG. 7, the processor 120 may determine that the second type of error has occurred in the solar power generation system when there are two or more photovoltaic modules 303 with the maximum power generation of zero for a second period of time for the same inverter 302. Hereinafter, for convenience of description, the second period of time is described as being 48 hours, but the present disclosure is not limited thereto. In addition, the processor 120 may extract information (702) about the photovoltaic modules, which are connected to the inverter to which an identifier is assigned and have unique identifiers assigned thereto, and send an alarm including this information to the user when the alarm-sending conditions are met.

For example, the processor 120 may receive information about photovoltaic modules A, B, C, D, and E with the maximum power generation of zero from the inverter 302 and update a database (701). In this case, module D may refer to a photovoltaic module that is connected to inverter number 1 and has a unique identifier assigned thereto. Accordingly, based on the information received on Jun. 28 and 29, 2023 indicating that module D has the maximum power generation of zero, the processor 120 may send an alarm to the user including information about module D.

Module E may refer to a photovoltaic module that is connected to inverter number 1 and has a unique identifier assigned thereto. Accordingly, based on the information received on Jun. 28 and 29, 2023, that module E has the maximum power generation of zero, the processor 120 may send an alarm to the user including information about module E.

Accordingly, based on the fact that modules B, D, and E satisfy the alarm-sending conditions according to the information about modules A, B, C, D, and E received on Jun. 28 and 29, 2023, the processor 120 may determine that the error occurring in the solar power generation system is the second type of error (CM002), and then send an alarm to the user including this information.

FIG. 8 is an exemplary diagram for describing the third type of error that occurs in the photovoltaic module according to an embodiment.

Referring to FIG. 8, the processor 120 may determine that the third type of error has occurred in the solar power generation system when the number of photovoltaic modules 303 with the maximum power generation of zero for a third period of time is half or more of the total number of photovoltaic modules 303 connected to the same inverter 302. Hereinafter, for convenience of description, the third period of time is described as being 24 hours, but the present disclosure is not limited thereto. In addition, the processor 120 may extract information (802) about the photovoltaic modules, which are connected to the inverter to which an identifier is assigned and have unique identifiers assigned thereto, and send an alarm including this information to the user when the alarm-sending conditions are met.

For example, the processor 120 may receive information about photovoltaic modules A, B, C, D, E, F, G, H, I, J, and K with the maximum power generation of zero from the inverter 302 and update a database (801). In this case, modules F, G, H, I, J, and K may refer to photovoltaic modules that are connected to inverter number 1 and have unique identifiers assigned thereto. Accordingly, based on the information received on Jun. 30 and Jul. 1, 2023 indicating that the maximum power generation of each of modules F, G, H, I, J, and K is zero, the processor 120 may send an alarm including information about modules F, G, H, I, J, and K to the user.

According to a database (802), which reflects the number of modules connected to each inverter, the number of photovoltaic modules connected to inverter number 1 is 10, and thus, the processor 120 may determine that the third type of error (CM003) has occurred in the solar power generation system when five or more of the photovoltaic modules connected to inverter number 1 have the maximum power generation of zero for the third period of time.

Accordingly, based on the fact that modules B, D, and E satisfy the alarm-sending conditions according to the information received on Jun. 30, 2023, and modules B, D, E, F, G, H, I, J, and K satisfy the alarm-sending conditions according to the information received on Jul. 1, 2023, the processor 120 may determine that the error occurring in the solar power generation system is the third type of error (CM003), and then send an alarm to the user including this information.

The above description of the present specification is only exemplary, and it will be understood by those skilled in the art that various modifications can be made without departing from the scope of the present disclosure and without changing essential features. Therefore, the above-described embodiments should be understood to be exemplary and not limiting in every aspect. For example, each component described as a single entity may be distributed and implemented, and components described as being distributed may also be implemented in a combined form.

When there is no apparent description of the order of operations constituting the method according to the present disclosure or a contrary description thereof, the operations may be performed in an appropriate order. The present disclosure is not limited to the described order of the operations. The use of all examples or exemplary terms (for example, and the like) in the present disclosure are to simply describe the present disclosure in detail, and unless the range of the present disclosure is not limited by the examples or the exemplary terms unless limited by the claims. In addition, it would be apparent to those of ordinary skill in the art that various modifications and changes may be easily made without departing from the scope and spirit of the present disclosure.

Therefore, it should be noted that the spirit of the present disclosure is not limited to the embodiments described above, and not only the claims to be described below, but also all ranges equivalent to or equivalently changed from the claims fall within the scope of the spirit of the present disclosure.

1. A method of monitoring a solar power generation system, the method comprising:
receiving information about a solar power generation system from an inverter;
determining whether an error has occurred in the inverter or photovoltaic modules based on whether the information is received; and
outputting a layout diagram of the solar power generation system based on a type of error of the photovoltaic module when an error has occurred in the photovoltaic module, and sending an alarm,
wherein the determining of whether an error has occurred includes determining that an error has occurred in the inverter when the information is not received, determining whether an error has occurred in the photovoltaic module based on the information when the information is received, and determining the type of error when it is determined that an error has occurred in the photovoltaic module.

2. The method of claim 1, wherein the determining of whether an error has occurred includes determining the type of error by obtaining a unique identifier of the photovoltaic module, in which an error has occurred, when the information is received and it is determined that an error has occurred in the photovoltaic module based on the information.

3. The method of claim 1, wherein the determining of whether an error has occurred includes determining the type of error based on the number of photovoltaic modules with a maximum power generation of zero and a duration of the maximum power generation of zero in the received information.

4. The method of claim 3, wherein the determining of whether an error has occurred includes determining that the error is a first type of error when there is one photovoltaic module with the maximum power generation of zero and the duration of the maximum power generation of zero is greater than or equal to a predetermined period of time,
determining that the error is a second type of error when there are two or more photovoltaic modules with the maximum power generation of zero and the duration of the maximum power generation of zero is greater than or equal to a predetermined period of time, and determining that the error is a third type of error when the number of photovoltaic modules with the maximum power generation of zero is half or more of the total number of a plurality of photovoltaic modules and the duration of the maximum power generation of zero is greater than or equal to a predetermined period of time.

5. The method of claim 1, wherein the outputting of the layout diagram includes outputting the layout diagram that corresponds to an actual arrangement of the photovoltaic modules, with different colors mapped for each type of error.

6. The method of claim 2, wherein the sending of the alarm includes sending the alarm corresponding to the type of error for the solar power generation system to which the unique identifier is assigned.

7. An apparatus for monitoring a solar power generation system,
the apparatus comprising:
at least one memory; and
at least one processor,
wherein the at least one processor is configured to:
receive information about a solar power generation system from an inverter;
determine whether an error has occurred in the inverter or photovoltaic modules based on whether the information is received; and
output a layout diagram of the solar power generation system based on a type of error of the photovoltaic module when an error has occurred in the photovoltaic module, and send an alarm, and
the at least one processor is further configured to determine that an error has occurred in the inverter when the information is not received,
determine whether an error has occurred in the photovoltaic module based on the information when the information is received, and
determine the type of error when it is determined that an error has occurred in the photovoltaic module.

8. The apparatus of claim 7, wherein the at least one processor is further configured to determine the type of error by obtaining a unique identifier of the photovoltaic module, in which an error has occurred, when the information is received and it is determined that an error has occurred in the photovoltaic module based on the information.

9. The apparatus of claim 7, wherein the at least one processor is further configured to determine the type of error based on the number of photovoltaic modules with a maximum power generation of zero and a duration of the maximum power generation of zero in the received information.

10. The apparatus of claim 9, wherein the at least one processor is further configured to determine that the error is a first type of error when there is one photovoltaic module with the maximum power generation of zero and the duration of the maximum power generation of zero is greater than or equal to a predetermined period of time,
determine that the error is a second type of error when there are two or more photovoltaic modules with the maximum power generation of zero and the duration of the maximum power generation of zero is greater than or equal to a predetermined period of time, and determining that the error is a third type of error when the number of photovoltaic modules with the maximum power generation of zero is half or more of the total number of a plurality of photovoltaic modules and the duration of the maximum power generation of zero is greater than or equal to a predetermined period of time.

11. The apparatus of claim 7, wherein the at least one processor is further configured to output the layout diagram that corresponds to an actual arrangement of the photovoltaic modules, with different colors mapped for each type of error.

12. The apparatus of claim 8, wherein the at least one processor is further configured to send the alarm corresponding to the type of error for the solar power generation system to which the unique identifier is assigned.

13. A computer-readable recording medium having recorded thereon a program for causing the method of claim 1 to be executed on a computer.
